(19) United States
(12) Patent Application Publication
(10) Pub. No.: US 2010/0108375 A1
(43) Pub. Date: May 6, 2010

(54) CONNECTION BOX FOR SOLAR MODULE

(76) Inventor: Michael RICHTER, Schalksmuehle (DE)

Correspondence Address: K.F. ROSS P.C., 5683 RIVERDALE AVENUE, SUITE 203 BOX 900, BRONX, NY, 10471-0900, US

(21) Appl. No.: 12/434,729

(22) Filed: May 4, 2009

(30) Foreign Application Priority Data
May 3, 2008 (DE) 102008022055.8

(51) Int. Cl. H05K 5/00

(52) U.S. Cl. 174/520

(57) ABSTRACT

A box for connecting an output line of a solar panel with a feed cable has a base mountable on the solar panel, formed with at least one cutout through which the feed cable passes, and having a generally planar floor and around the floor a seal seat open orthogonally in one direction of the floor. A cover is engageable oppositely of the direction with the base to from therewith a compartment. Functional elements are provided in the compartment, A seal in the seat is engaged between the base and the cover.

### FIELD OF THE INVENTION

The present invention relates to a connection box. More particularly this invention concerns a connection box for a solar panel.

### BACKGROUND OF THE INVENTION

A standard connection box for a solar panel has a base mounted on solar panel and forming a compartment for circuit elements. A solar-panel output line feeds electricity generated by the panel into the box and a feed cable is connected in the box to the solar-panel output line and in turn feeds the electricity to the network or user. A cover closes the base and a seal between the cover and the base hermetically seals the compartment they define.

Such connection boxes are known, for example, from U.S. Pat. No. 4,623,753, DE 20 2005 008 385, or US 2005/0161080. Here the cover has a collar extending toward the base of the connection box. A groove is formed along the peripheral surface of the collar, in which a sealing ring, in particular an O-ring, is inserted. Upon placement of the cover on the base of the connection box, the sealing ring seals the compartment against external influences, in particular dirt and moisture, by engagement of the seal between the floor of the groove and the outer flank of the annular groove.

In addition to the opening closable by the cover, the base has in its wall forming the compartment further holes or cutouts that are provided for the feed cables. These openings are also closed to the external environment using suitable seals. The seals are supported on the lateral surface of the feed cable.

The seals are entirely usable in regard to their action, but are in need of improvement in their design and configuration in regard to manufacturing which is automated as is completely as possible.

### OBJECTS OF THE INVENTION

It is therefore an object of the present invention to provide an improved connection box for a solar module.

Another object is the provision of such an improved connection box for a solar module that overcomes the above-given disadvantages, in particular that is improved in regard to automated manufacturing.

### SUMMARY OF THE INVENTION

A box for connecting an output line of a solar panel with a feed cable has according to the invention a base mountable on the solar panel, formed with at least one cutout through which the feed cable passes, and having a generally planar floor and around the floor a seal seat open orthogonally in one direction of the floor. A cover is engageable oppositely of the direction is with the base to from therewith a compartment. Functional elements are provided in the compartment, A seal in the seat is engaged between the base and the cover.

The base of the connection box is typically equipped with circuit elements, in particular contacts and bridge diodes, in a direction orthogonal to its floor. It is a significant advantage if the seal may also be inserted in the same direction according to the solution according to the invention, because this significantly reduces the manufacturing effort.

An embodiment which is characterized in that the shared seal of the cover and the base additionally seals the connection-box-side cable routing cutout is especially preferred.

Automated manufacturing is further simplified by this advantageous refinement. Only one seal is still required to seal the cover and the side cable routing cutout. Not only does this optimize assembly but also the combination of components which were separate until now, so that the number of the assembly steps may be reduced overall.

To this end, the seal is provided with a cable routing opening for the feed cable. The seal function of the seal is ensured in that the cable routing opening of the seal has a smaller diameter than the diameter of the feed cable and the outer surface of the feed cable inserted in the region of the cable routing opening is used as a sealing surface by the seal.

In order to also be able to install the feed cable in a direction orthogonal to the base of the base, an embodiment is proposed which is characterized in that the seal is constructed in two parts in the region of its cable routing opening such that a lower part of the feed cable is insertable into the cable routing opening in the orthogonal direction to the base of the base. Then an insert part of the seal is fitted in the recess over the cable. Automated manufacturing is made significantly easier by this refinement of the assembly direction of the feed cable, which was parallel to the base of the base until now.

In the above-mentioned embodiment, it is advantageous if the second part of the seal can be placed on the first part via a tongue-and-groove connection.

In general, it is provided that the base forms the holder or seat for the seal. In particular, the base has an outer peripheral wall and an inner peripheral wall between which a peripheral annular gap is formed that forms the holder or seat for the seal. The seal function of the seal may be improved further in that the seal forms a lip extending toward the cover and projecting beyond the outer peripheral wall toward the cover, in particular if the cover is formed with a groove for accommodating the sealing lip on the base. Furthermore, it is considered that the seal forms a recess for accommodating a cover-side collar. In combination, an embodiment results here which is characterized in that the cover-side collar, the recess of the seal, the sealing lip, and the cover-side groove are situated in sequence in the direction of the compartment such that a labyrinth seal is provided.

### BRIEF DESCRIPTION OF THE DRAWING

The above and other objects, features, and advantages will become more readily apparent from the following description, reference being made to the accompanying drawing in which:

FIG. 1 is an exploded perspective view from above of the box according to the invention;

FIG. 2 is a perspective view from above of the assembled base of the box;

FIG. 3 is a view like FIG. 1 of another box according to the invention;

FIG. 4 is a perspective view from above of the FIG. 3 seal;

FIG. 5 is an exploded perspective view from above of the seal assembly; and

FIG. 6 is a section taken along line VI-VI of FIG. 1.

### SPECIFIC DESCRIPTION

As seen in the drawing a connection box 10 has a cover 11 and a base 12. The base 12 has an outer side wall 13 projecting upward toward the cover and an inner side wall 15 extending parallel to and spaced from the base 12 by an annular gap 14. (The references to “up” and “down” being purely for convenience of description, since the box is often mounted inverted on the generally downwardly facing back face of a solar panel.)

Two opposite outer surfaces of the side wall 13 are formed with locking lug guide ridges 16 that are interrupted by tool-engagement formations 17. The locking lug guide webs 16 form a seat in which wedge-shaped locking projections 18 are formed on the outer surfaces of the side wall 13.

Feed cables 20 are routed into the interior of the connection box 10 through cable holes or cutouts 19 in the side wall 13. The stripped inner ends of these cables 20 are used to contact solar-panel output conductors 21 in a chamber 22 of the base 12. The feed cables 20 carry contacts 23 that are crimped on their stripped wire ends for electrical connection to the panel-output conductors 21.

A vent 24 connects the compartment 22 to the external environment via holes 25 provided in the side wall 13. The formation of condensed water and super or subatmospheric pressures are thus prevented in the compartment 22. A bridge diode 26 is in an electrical connection with the two the feed cables 20 shown in the illustrated embodiment. Parts such as the bridge diode 26, the vent 24, or the clamping contacts 23 are considered functional elements.

A seal 27 formed with a lip 28 projecting toward the cover is fitted to the base gap 14. When the cover 11 is placed on the base, the lip 28 presses against bottom and side surfaces of the cover. Furthermore, the seal 27 forms cable routing openings 29 through which the feed cables 20 pass into the chamber 22.

The cable openings 29 have a diameter that is slightly smaller than the cable outside diameter, so that the inner edges of the cable openings press against the side surfaces of the feed cables 20 to form seals. In connection with the sealing lip 28, the compartment 22 is protected against external influences, in particular moisture and contamination, with the aid of only a single seal 27.

The cover 11 forms locking lugs 30 that project downward toward the base 12 and that fit with the locking lug guide webs 16 and the locking projections 18 and anchor the cover 11 solidly on the base 12 when the box 10 is closed, on opposing edges. Using the tool-engagement formation 17, a tool which spreads the locking lugs 30 may be introduced into the region of the locking projections 18 in order to open the connection box 10.

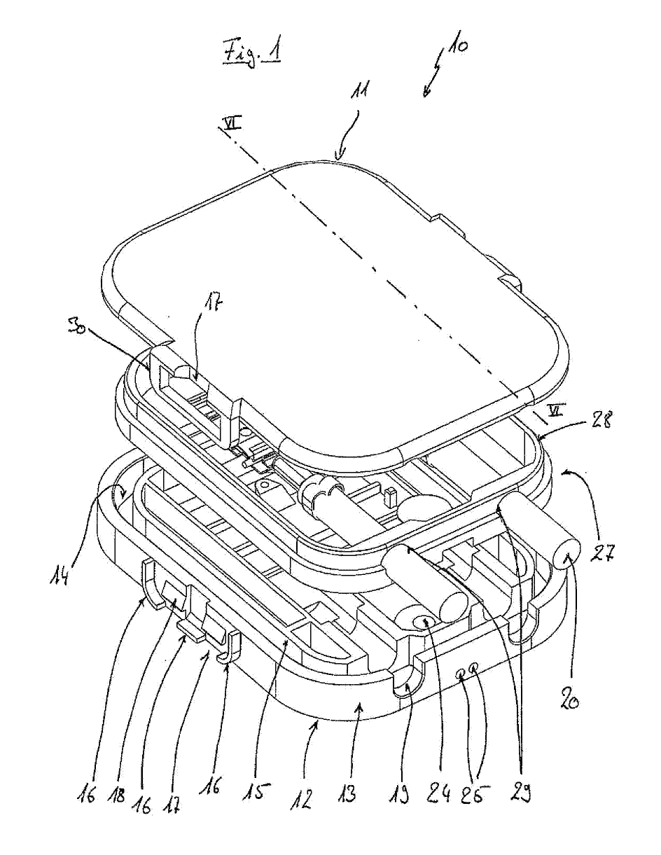

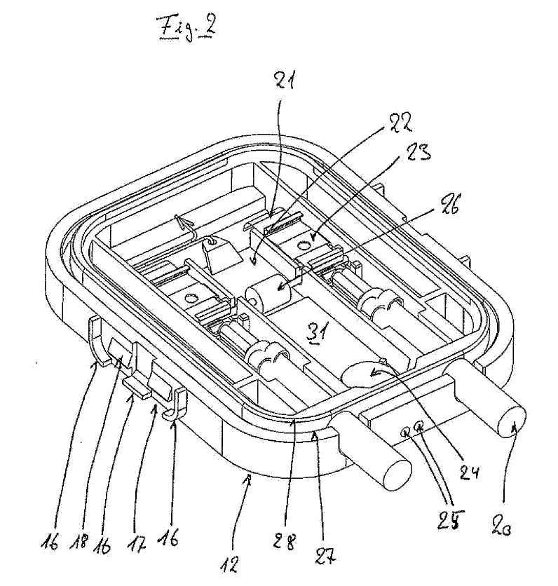

The essential advantage in the embodiment according to FIGS. 1 and 2 of the invention is the arrangement of the seal 27 in an annular chamber 14 that is open toward the cover 11 and/or is plane-parallel to a generally rectangular and planar floor 31 of the base 12 and that is used as a holder or seat for the seal 27. This advantageously allows the assembly direction for the diverse circuit elements, which is oriented orthogonally to a plane of the flat floor 31, to also be used for the insertion of the seal 27 into the base 12. In the present example, in particular the bridge diode 26 and the contact of the clamping contact 23, which is placed in the overlap region of wire end of the feed cable 20 and the panel-output conductor 21, are mounted in the above-mentioned orthogonal direction.

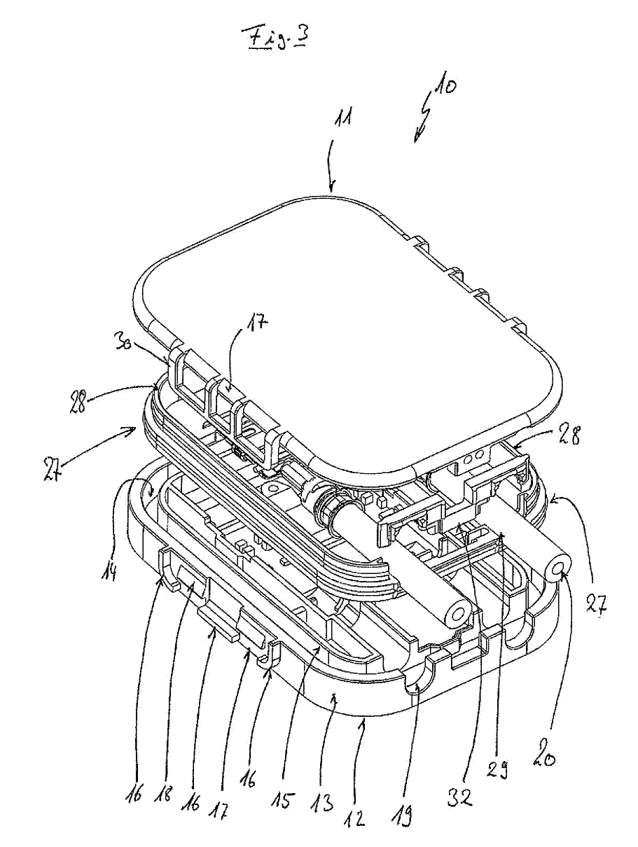

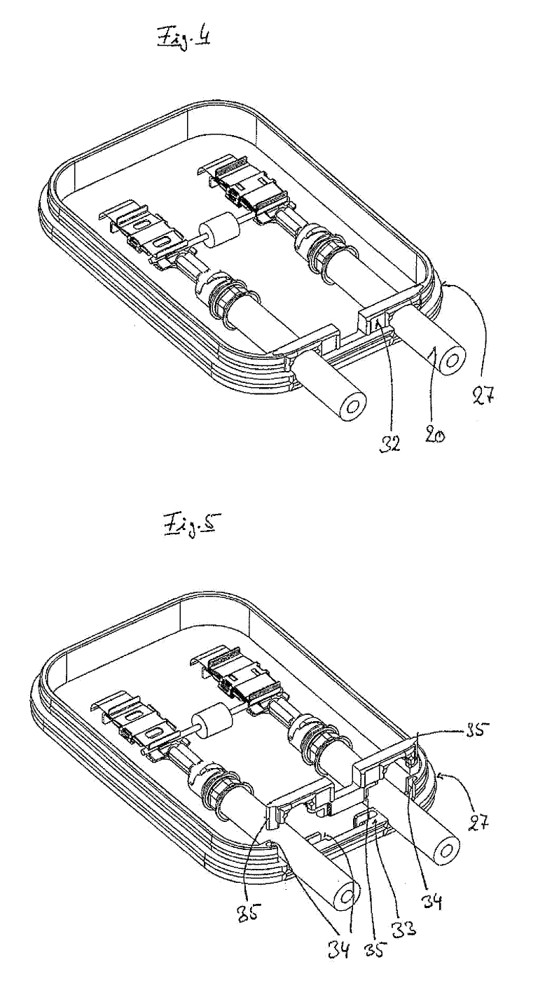

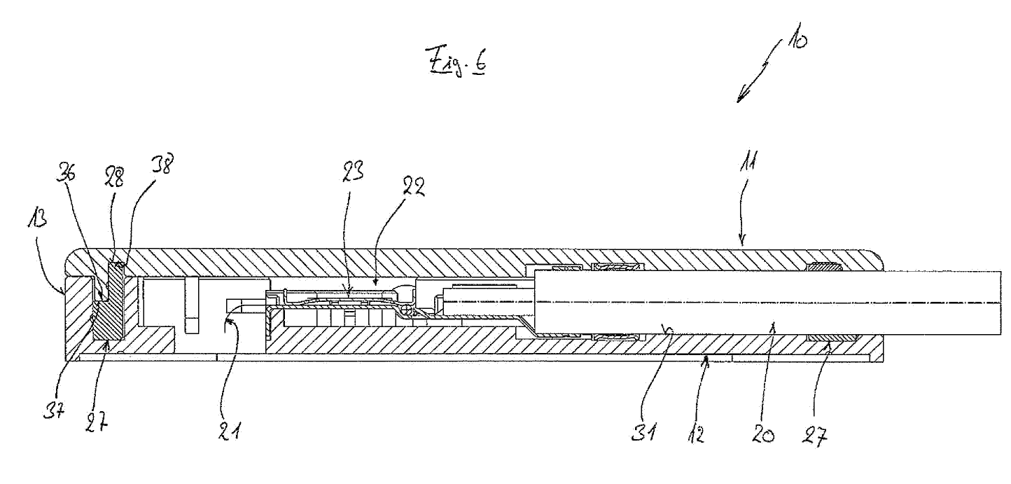

A second embodiment of the invention is shown in FIGS. 3 through 5 in which features that are functionally identical to those of FIGS. 1 and 2 bear the same reference numerals.

In contrast to the preceding embodiment, the seal is formed in two parts. In the region of the cable routing openings 29, the seal 27 has an approximately U-shaped recess into which a seal insert 32 may be introduced. The separation plane 33 between seal 27 and seal insert 32 runs parallel to the base 31 and cuts through the cable routing openings in the seal 27 such that the seal 27 and the seal insert 32 form corresponding, approximately semicircular cable routing openings.

In the region of the recess, the recess edge of the seal 27 is formed with grooves 34 in which springs 35 of the seal insert 32 engage and hold the seal insert 32 in the seal 27. The tongue-and-groove arrangement is precisely fitted such that penetration of moisture and dirt is not possible along the partition planes between the seal 27 and the seal insert 32.

In FIG. 6 the seal 27 has a recess 36 in which a collar 37 of the cover 11 engages. This is adjacent on the seal side to the sealing lip 28, which extends beyond the height of the side wall 13 of the base 12 extending toward the cover 11 and is inserted in a cover-side seal groove 38. The arrangement of the recess 36 with the collar 37 and the sealing lip 28 having corresponding sealing groove 38, which is sequential toward the compartment 22, forms a labyrinth-type seal arrangement.

In summary, a connection box 10 is disclosed whose advantageous holder for a seal 27 allows an assembly direction of the seal 27 that is orthogonal to the base 31 and is distinctly advantageous from an assembly viewpoint. By dividing the seal 27 in the region of its cable routing openings 29, the assembly direction oriented orthogonally to the base 31 may also be implemented for insertion of the feed cables 20 into the compartment 22. The connection box 10 according to the invention thus significantly improves the automated manufacturing in its embodiments

I claim:

1. A box for connecting an output line of a solar panel with a feed cable, the box comprising:
a base mountable on the solar panel formed with at least one cutout through which the feed cable passes and that has a generally planar floor and around the floor a seal seat open orthogonally in one direction of the floor;
a cover engageable oppositely of the direction with the base to from therewith a compartment;
functional elements in the compartment; and
a seal in the seat engaged between the base and the cover.

2. The connection box defined in claim 1 wherein the seal also fits around the cable passing through the cutout.

3. The connection box defined in claim 2 wherein the seal is formed with a cutout that fits around the cable.

4. The connection box defined in claim 3 wherein the cutout of the seal has a smaller diameter than the cable.

5. A box for connecting an output line of a solar panel with a feed cable, the box comprising:
a base mountable on the solar panel formed with at least one cutout through which the feed cable passes and that has a generally planar floor and around the floor a seal seat open orthogonally in one direction of the floor;
a cover engageable oppositely of the direction with the base to from therewith a compartment;
functional elements in the compartment; and
a seal engaged between the base and the cover and having
an annular lower part in the seat and passing underneath the cable in the cutout and formed at the cutout with a recess open in the direction, and
an insert seal part fitting in the recess over the cable and sealing therearound and with the lower part.

6. The connection box defined in claim 5 wherein the insert part and lower part are formed with interfitting and complementary tongue-and-groove formations.

7. The connection box defined in claim 5 wherein the base is unitarily formed with the seat for the seal.

8. The connection box defined in claim 7 wherein the base is formed with a pair of spaced annular walls forming a gap that is the seat.

9. The connection box defined in claim 8 wherein the seal has a lip projecting in the direction past the walls and the cover is formed with a groove complementary to and receiving the lip.

10. The connection box defined in claim 9 wherein the cover has an annular rim projecting opposite to the direction and the seal has a recess adjacent the lip in which the rim fits.

11. The connection box defined in claim 10 wherein the lip, recess, and rim form a labyrinth seal.
